(19) United States
(12) Patent Application Publication
(10) Pub. No.: US 2025/0334629 A1
(43) Pub. Date: Oct. 30, 2025

(54) SEMICONDUCTOR DEVICE

(71) Applicant: ROHM Co., Ltd., Kyoto (JP)

(72) Inventor: Takumi Yamada, Kyoto (JP)

(73) Assignee: ROHM Co., Ltd., Kyoto (JP)

(21) Appl. No.: 19/095,001

(22) Filed: Mar. 30, 2025

(30) Foreign Application Priority Data
Apr. 30, 2024 (JP) 2024-073459

(51) Int. Cl. G01R 31/28

(52) U.S. Cl. CPC G01R 31/2884; G01R 31/2882

(57) ABSTRACT

A semiconductor device (1) includes: a logic circuit (11); and a diagnostic circuit (120), configured so as to perform a diagnostic process of diagnosing whether the logic circuit is in a state capable of normal operation based on output data of the logic circuit when a test pattern is supplied to the logic circuit. The diagnostic circuit executes multiple diagnostic processes with operating conditions of the logic circuit differing from each other.

### CROSS-REFERENCE TO RELATED APPLICATION

This application claims the priority benefit of Japan application serial no. 2024-073459, filed on Apr. 30, 2024. The entirety of the above-mentioned patent application is hereby incorporated by reference herein and made a part of this specification.

### BACKGROUND

### Technical Field

The disclosure relates to a semiconductor device.

### Description of Related Art

Built-in-self-test (BIST) is known as a technique of design for testability for circuits (e.g., Japanese Patent Application Laid-open No. 2020-165780). BIST for logic circuits is sometimes called logic BIST.

In a semiconductor device having a logic circuit and capable of BIST, whether the logic circuit can operate normally is confirmed by preforming diagnosis using BIST at the time of startup. However, the current diagnostic technology using BIST may be insufficient from the viewpoint of ensuring reliability.

### SUMMARY

A semiconductor device according to an aspect of the disclosure includes: a logic circuit; a diagnostic circuit, configured so as to perform a diagnostic process of diagnosing whether the logic circuit is in a state capable of normal operation based on output data of the logic circuit when a test pattern is supplied to the logic circuit, and the diagnostic circuit executes a plurality of diagnostic processes with operating conditions of the logic circuit that differ from each other.

### BRIEF DESCRIPTION OF THE DRAWINGS

FIG. 1 is a configuration diagram of a semiconductor device according to an embodiment of the disclosure and its periphery.

FIG. 2 is a partial block diagram of a semiconductor device according to an embodiment of the disclosure.

FIG. 3 is an operation flowchart of a semiconductor device according to an embodiment of the disclosure.

FIG. 4 is a flowchart of a diagnostic sequence operation according to an embodiment of the disclosure.

FIG. 5 is an explanatory diagram of three diagnostic operating conditions according to a first example belonging to an embodiment of the disclosure.

FIG. 6 is an explanatory diagram of five diagnostic operating conditions according to a second example belonging to an embodiment of the disclosure.

FIG. 7 is an explanatory diagram of two diagnostic operating conditions according to a third example belonging to an embodiment of the disclosure.

FIG. 8 is a configuration diagram of a drive voltage generation circuit according to a seventh example belonging to an embodiment of the disclosure.

FIG. 9 is a relationship diagram between control signals and drive voltages according to the seventh example belonging to an embodiment of the disclosure.

FIG. 10 is a configuration diagram of a circuit that generates and outputs a control signal according to the seventh example belonging to an embodiment of the disclosure.

FIG. 11 is a configuration diagram of an oscillator according to an eighth example belonging to an embodiment of the disclosure.

FIG. 12 is a relationship diagram between control signals and clock frequencies according to the eighth example belonging to an embodiment of the disclosure.

FIG. 13 is a configuration diagram of a circuit that generates and outputs the control signal according to the eighth example belonging to an embodiment of the disclosure.

FIG. 14 is a schematic configuration diagram of a power supply device according to a ninth example belonging to an embodiment of the disclosure.

FIG. 15 is a schematic configuration diagram of the power supply device according to the ninth example belonging to an embodiment of the disclosure.

FIG. 16 is a configuration diagram of one regulator according to a ninth example belonging to an embodiment of the disclosure.

### DESCRIPTION OF THE EMBODIMENTS

### Detailed Description

Hereinafter, examples of embodiments of the disclosure will be specifically described with reference to the drawings. In each referenced figure, the same parts are given the same reference numerals, and duplicate descriptions regarding the same parts are omitted in principle. In the specification, for the sake of simplification, information, signals, physical quantities, functional parts, circuits, elements or components, etc. may be omitted or abbreviated by indicating symbols or codes that reference such information, signals, physical quantities, functional parts, circuits, elements or components. For example, the high side voltage referred to as “VDD_{HIGH}” (see FIG. 5) may also be expressed as high side voltage VDD_{HIGH}, or may be abbreviated as voltage VDD_{HIGH}. Nevertheless, all of these expressions refer to the same thing.

First, descriptions are provided for several terms used in the description of embodiments of the disclosure. “Ground” refers to a reference conductor having a reference potential of 0V (zero volt) or refers to the 0V potential itself. The reference conductor may be formed using a conductor such as metal. The potential of 0V may also be referred to as a ground potential. In the embodiments of the disclosure, a voltage shown without specifying a particular reference represents a potential as viewed from the ground. Level refers to the level of potential, and for any signal or voltage of interest, a high level has a higher potential than a low level.

For any transistor configured as a field effect transistor (FET) exemplified by a MOSFET, an ON state refers to a state in which conduction exists between the drain and the source of the transistor, and an OFF state refers to a state in which there is no conduction between the drain and the source of the transistor (blocked state). The same applies to transistors not classified as an FET. Unless otherwise specified, a MOSFET is understood as an enhancement-type MOSFET. MOSFET is an abbreviation for “metal-oxide-semiconductor field-effect transistor”. Also, unless otherwise specified, in any MOSFET, the back gate may be considered to be shorted to the source.

Any switch can be configured with one or more field effect transistors (FETs), and when a certain switch is in the ON state, conduction exists between both ends of the switch, while when a certain switch is in the OFF state, there is no conduction between both ends of the switch. Hereinafter, for any transistor or switch, the ON state and the OFF state may be simply expressed as ON and OFF.

The connection between multiple parts forming a circuit, such as arbitrary circuit elements, wiring, nodes, etc., may be understood as referring to electrical connection unless otherwise specified.

In the case where any two voltages to be compared are a voltage v1 and a voltage v2, “v1>v2” indicates that the voltage v1 is higher than the voltage v2, “v1<v2” indicates that the voltage v1 is lower than the voltage v2, and “v1=v2” indicates that the value of the voltage v1 is the same as the value of the voltage v2. The same applies to other expressions including physical quantities other than voltage.

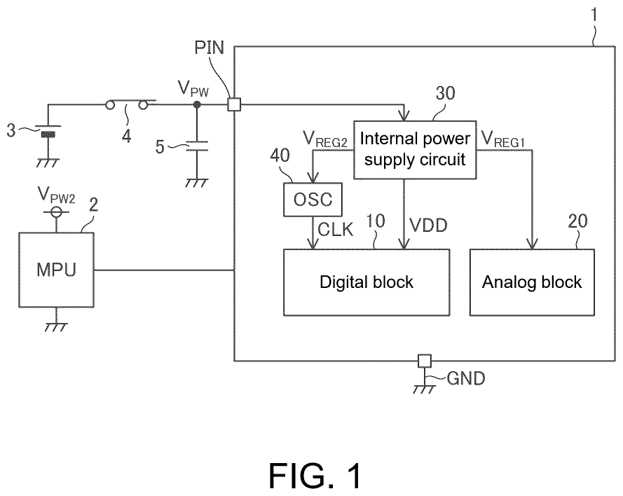

FIG. 1 illustrates a semiconductor device 1 according to an embodiment of the disclosure and its periphery. The semiconductor device 1 is an electronic component including a semiconductor chip having a semiconductor integrated circuit formed on a semiconductor substrate, a housing (package) accommodating the semiconductor chip, and multiple external terminals exposed from the housing to the outside of the semiconductor device 1. The semiconductor device 1 is formed by encapsulating the semiconductor chip in the housing (package) formed of resin. In FIG. 1, only a power terminal PIN and a ground terminal GND included in the multiple external terminals are illustrated, but other external terminals are also provided on the semiconductor device 1. Wiring provided outside the semiconductor device 1 may be specifically referred to as external wiring.

A micro processing unit (MPU) 2 is an example of an external device provided outside the semiconductor device 1. A voltage source 3 is a DC voltage source that outputs a positive DC voltage. The system including the semiconductor device 1 and the MPU 2 may be mounted in a vehicle such as an automobile. In such case, the voltage source 3 may also be a battery mounted in the vehicle. The voltage source 3 is provided between the ground and the first end of a switch 4, and the second end of the switch 4 is connected to the power terminal PIN through external wiring. Also, an input capacitor 5 is provided between the second end of the switch 4 and the ground. The voltage applied to the power terminal PIN is referred to as a power voltage V_{PW}. The semiconductor device 1 operates based on the power voltage V_{PW}. The ground terminal GND is connected to the ground.

When the switch 4 is in an OFF state and there is no accumulated charge in the input capacitor 5, the power voltage V^{PW} is 0V (zero volt). When the switch 4 is switched from the OFF state to the ON state by setting the state where the power voltage V_{PW} is 0V as the start point, the power voltage V_{PW} rises to the output voltage of the voltage source 3 while charging the input capacitor 5. The semiconductor device 1 can start up when the power voltage V_{PW} is equal to or higher than a positive predetermined voltage V_{UVLO}. The output voltage of the voltage source 3 is higher than the predetermined voltage V_{UVLO}.

The MPU 2 is connected to the ground. The MPU 2 receives the supply of a power voltage V_{PW2} having a positive DC voltage value and is driven based on the power voltage V_{PW2}. The power voltage V_{PW2} for the MPU 2 may be the same as or different from the power voltage VPW for the semiconductor device 1. The power voltage V_{PW2} may be supplied to the MPU 2 from a voltage source that is not shown. In the case where a power supply device is formed by using the semiconductor device 1, one of the output voltages generated by the power supply device may be used as the power voltage V_{PW2}.

The semiconductor device 1 and the MPU 2 are connected to each other through one or more external wirings. The semiconductor device 1 and the MPU 2 may be connected in a manner that enables bidirectional communication, and at this time, a serial peripheral interface (SPI) can be used as the interface for the bidirectional communication between the semiconductor device 1 and the MPU 2, or an interface using the inter-integrated circuit (I²C) or Microwire can be used.

The semiconductor device 1 includes a digital block 10, an analog block 20, an internal power supply circuit 30, and an oscillator 40.

The digital block 10 is formed by numerous digital circuits. The digital circuits provided in the digital block 10 include at least a sequential circuit that operates in synchronization with a clock signal CLK, and may further include a combinational circuit. A drive voltage VDD, which is a positive DC voltage, is supplied to the digital block 10, and each digital circuit in the digital block 10 operates based on the drive voltage VDD.

The analog block 20 is formed by numerous analog circuits. A drive voltage V_{REG1}, which is a positive DC voltage, is supplied to the analog block 20, and each analog circuit in the analog block 20 operates based on the drive voltage V_{REG1}.

The internal power supply circuit 30 generates multiple internal power supply voltages based on the power voltage V_{PW} supplied to the power terminal PIN. The multiple internal power supply voltages include drive voltages VDD, V_{REG1}, and V_{REG2}. The internal power supply circuit 30 supplies the drive voltage VDD to the digital block 10, supplies the drive voltage V_{REG1} to the analog block 20, and the drive voltage V_{REG2} to the oscillator 40. The drive voltages VDD, V_{REG1}, and V_{REG2} all exhibit positive DC voltage values. However, the value of the drive voltage VDD is intentionally varied, albeit temporarily (details to be described later). Here, the supply voltage to the analog block 20 is referred to as the drive voltage V_{REG1}, and the supply voltage to the oscillator 40 is referred to as the drive voltage V_{REG2}, but the drive voltage V_{REG1} and the drive voltage V_{REG2} may be a common voltage. The drive voltages VDD, V_{REG1}, and V_{REG2} may all be a common voltage.

The oscillator 40 performs an oscillation operation based on the drive voltage V_{REG2} to generate the clock signal CLK, and supplies the generated clock signal CLK to the digital block 10. The clock signal CLK is a rectangular wave signal that alternately exhibits signal levels of a high level and a low level. The frequency of the clock signal CLK is hereinafter referred to as a clock frequency f_{CLK}.

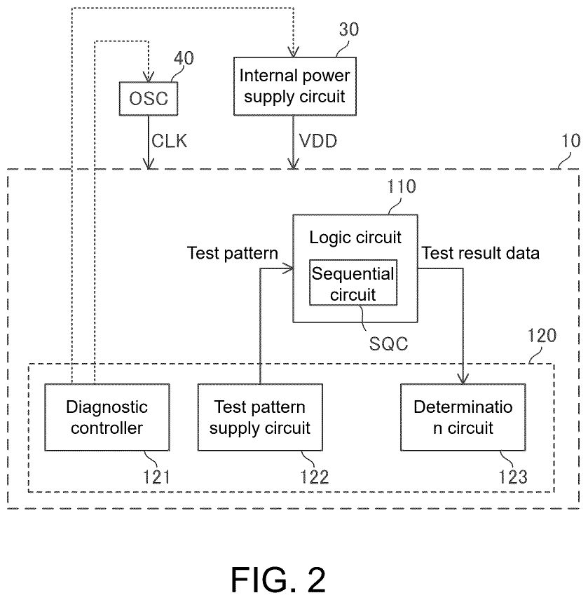

FIG. 2 shows a schematic internal configuration of the digital block 10. The digital block 10 includes a logic circuit 110 and a diagnostic circuit 120. The logic circuit 110 is a logic circuit (target logic circuit) that serves as a target for a diagnostic process. The diagnostic circuit 120 includes a diagnostic controller 121, a test pattern supply circuit 122, and a determination circuit 123. The diagnostic circuit 120 tests the operation of the logic circuit 110 by executing a diagnostic process on the logic circuit 110. Through testing the operation of the logic circuit 110, it is diagnosed whether the logic circuit 110 is in a state capable of normal operation.

The logic circuit 110 has a sequential circuit SQC that operates in synchronization with the clock signal CLK. However, a combinational circuit that operates asynchronously with the clock signal CLK may also be included in the logic circuit 110. The diagnostic controller 121, the test pattern supply circuit 122, and the determination circuit 123 also each have a sequential circuit that operates in synchronization with the clock signal CLK. However, a combinational circuit that operates asynchronously with the clock signal CLK may also be included in the diagnostic controller 121, the test pattern supply circuit 122, or the determination circuit 123. The sequential circuit SQC in the logic circuit 110 includes a flip-flop, a latch circuit, etc., that operate in synchronization with the clock signal CLK. The sequential circuit in the diagnostic controller 121, the test pattern supply circuit 122, or the determination circuit 123 is similar.

In the diagnostic process, under the control of the diagnostic controller 121, the test pattern supply circuit 122 generates a test pattern and supplies the test pattern to the logic circuit 110. The test pattern is data (a bundle of digital signals) beneficial for diagnosing the presence or absence of a fault in the logic circuit 110, and is held in advance in the diagnostic circuit 120. The test pattern supply circuit 122 supplies the test pattern to the logic circuit 110 in synchronization with the clock signal CLK.

In the diagnostic process, the logic circuit 110 generates test result data by applying a digital signal process to the supplied test pattern. The test result data is output from the logic circuit 110 to the determination circuit 123. The digital signal process is executed in synchronization with the clock signal CLK. That is, the digital signal process is executed by using the sequential circuit SQC that operates in synchronization with the clock signal CLK. In the diagnostic process, the logic circuit 110 outputs the test result data to the determination circuit 123 in synchronization with the clock signal CLK. In the diagnostic process, the determination circuit 123 can determine the presence or absence of a fault in the logic circuit 110 by comparing the test result data with expected data. The expected data is held in advance in the diagnostic circuit 120 as data corresponding to the test pattern.

The state in which the logic circuit 110 operates normally (the state in which the logic circuit 110 operates as designed) is referred to as the normal state. The state in which the logic circuit 110 does not operate normally (the state in which the logic circuit 110 cannot operate as designed) is referred to as the abnormal state. The abnormal state corresponds to a state in which normal operation of the logic circuit 110 cannot be guaranteed.

The expected data corresponds to the normal data that is expected to be obtained from the logic circuit 110 when the test pattern is supplied to the logic circuit 110. Therefore, in the diagnostic process, when the test pattern is supplied to the logic circuit 110 in the normal state, the test result data matches the expected data. In the diagnostic process, when the test pattern is supplied to the logic circuit 110 in the abnormal state, the test result data does not match the expected data. The determination circuit 123 can determine that there is no fault in the logic circuit 110 (i.e., the logic circuit 110 is in the normal state) when the test result data matches the expected data. The determination circuit 123 can determine that there is a fault in the logic circuit 110 (i.e., the logic circuit 110 is in the abnormal state) when the test result data differs from the expected data.

As a unique operation, the diagnostic circuit 120 performs multiple diagnostic processes with operating conditions of the logic circuit 110 that differ from each other. Each of the diagnostic processes is a built-in self-test (BIST), and each diagnostic process may be implemented by using the BIST technology. In each diagnostic process, BIST using scan testing can be utilized. It should be noted that BIST targeting a logic circuit is called logic BIST. Since BIST itself is well-known, detailed descriptions of individual diagnostic processes are omitted, and descriptions of the configuration within the logic circuit 110 are also omitted.

The diagnostic circuit 120 performs first to n^{th} diagnostic processes as the multiple diagnostic processes. n represents an arbitrary integer of 2 or greater. The operating condition of the logic circuit 110 in the i^{th} diagnostic process is referred to as the i^{th} diagnostic operating condition. i represents an arbitrary integer. That is, the diagnostic circuit 120 performs the first diagnostic process in the state where the operating condition of the logic circuit 110 is set to the first diagnostic operating condition, and performs the second diagnostic process in the state where the operating condition of the logic circuit 110 is set to the second diagnostic operating condition. When “n≥3”, the same applies to the third diagnostic process to the n^{th} diagnostic process. The diagnostic circuit 120 diagnoses whether the logic circuit 110 is in a state capable of normal operation based on the results of the first to n^{th} diagnostic processes.

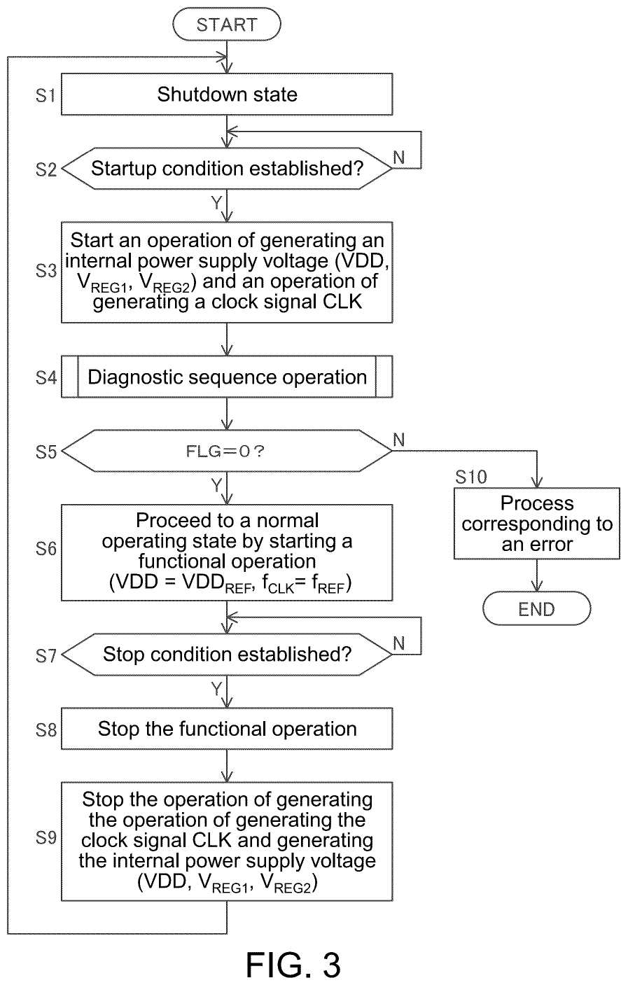

FIG. 3 shows an operation flowchart of the semiconductor device 1. First, in Step S1, the semiconductor device 1 is in a shutdown state. In the shutdown state, the semiconductor device 1 is not started up. In the shutdown state, the power supply voltage V^{PW} is 0V (or lower than the predetermined voltage V_{UVLO}). As one of the external terminals of the semiconductor device 1, an enable terminal (not shown) that receives an enable signal having a value of “0” or “1” may be provided. In such case, regardless of the power supply voltage V_{PW}, a state in which the enable signal having a value of “0” (for example, an enable signal of 0V) is supplied to the enable terminal may also belong to the shutdown state.

When the startup condition is satisfied with the shutdown state as the start point (Y in Step S2), the flow transitions to Step S3. The startup condition is satisfied when the power supply voltage V_{PW} transitions from a state lower than the predetermined voltage V_{UVLO} to a state equal to or higher than the predetermined voltage V_{UVLO}. In the case where the enable terminal is provided at the semiconductor device 1, the startup condition is satisfied when the value of the enable signal changes from “0” to “1” on the premise that the power supply voltage V_{PW} is equal to or higher than the predetermined voltage V_{UVLO}, or the startup condition is satisfied when the power supply voltage V_{PW} transitions from a state lower than the predetermined voltage V_{UVLO} to a state equal to or higher than the predetermined voltage V_{UVLO} on the premise that the value of the enable signal is “1”. For example, the value of the enable signal having a level equal to or higher than the predetermined voltage V_{UVLO} may be “1”, and the value of the enable signal having a level lower than the predetermined voltage V_{UVLO} may be “0”.

In Step S3, the internal power supply circuit 30 starts the generation operation of the internal power supply voltages including the drive voltage VDD, V_{REG1} and V_{REG2}. The generated drive voltage VDD is supplied to the digital block 10. After the start of the generation operation of the internal power supply voltages, except for the execution period of a diagnostic sequence operation to be described later, the drive voltage VDD matches a predetermined reference voltage VDD_{REF}. Furthermore, in Step S3, the generation operation of the clock signal CLK based on the drive voltage V_{REG2} by the oscillator 40 is started. The generated clock signal CLK is supplied to the digital block 10. After the start of the generation operation of the clock signal CLK, except for the execution period of the diagnostic sequence operation to be described later, the clock frequency f_{CLK} matches a predetermined reference frequency f_{REF}. After Step S3, the flow advances to Step S4.

In Step S4, the diagnostic sequence operation is executed by the diagnostic circuit 120. Multiple diagnostic processes are executed in the diagnostic sequence operation. The details of the diagnostic sequence operation will be described later. However, during the diagnostic sequence operation, a value of “0” or “1” is set to a flag FLG managed by the diagnostic circuit 120. After the diagnostic sequence operation of Step S4, in Step S5, the diagnostic controller 121 confirms whether the value of the flag FLG is “0”. If the value of the flag FLG is “0” (Y in Step S5), the process advances from Step S5 to Step S6, and if the value of the flag FLG is “1” (N in Step S5), the process advances from Step S5 to Step S10.

In Step S6, a predetermined functional operation by a functional circuit provided in the semiconductor device 1 is started. Before reaching Step S6, the functional operation is in a non-execution state. The functional circuit includes the logic circuit 110 and each analog circuit in the analog block 20 as components. Therefore, the functional operation is executed by using the logic circuit 110. The content of the functional operation varies according to the type of the semiconductor device 1.

With the functional operation being started, in Step S6, the state of the semiconductor device 1 reaches the normal operating state. In the normal operating state, the functional operation continues being executed. In principle, the semiconductor device 1 is configured so that “VDD=VDD_{REF}”, and only during the execution period of the diagnostic sequence operation, the drive voltage VDD may be changed from the reference voltage VDD_{REF}. In principle, the semiconductor device 1 is configured so that “f_{CLK}=f_{REF}”, and only during the execution period of the diagnostic sequence operation, the clock frequency f_{CLK} may be changed from the reference frequency f_{REF}. When the diagnostic sequence operation ends (when all of the diagnostic processes in the diagnostic sequence operation are completed), before reaching Step S6, the drive voltage VDD is fixed to the reference voltage VDD_{REF} and the clock frequency f_{CLK} is fixed to the reference frequency f_{REF} by the logic circuit 110. Therefore, in the normal operating state, the drive voltage VDD matches the reference voltage VDD_{REF} and the clock frequency f_{CLK} matches the reference frequency f_{REF}.

In Step S7 following Step S6, the semiconductor device 1 determines whether a stop condition is satisfied. In Step S7, in the case where the stop condition is satisfied (Y in Step S7), the flow transitions from Step S7 to Step S8, and in Step S8, the functional circuit stops the functional operation and then the flow proceeds to Step S9. If the stop condition is not satisfied (N in Step S7), the normal operating state of the semiconductor device 1 is maintained, and thereafter, the determination process of Step S7 is repeated. The stop condition is satisfied when the power supply voltage V_{PW} transitions from the state of being equal to or higher than the predetermined voltage V_{UVLO} to the state of being lower than the predetermined voltage V_{UVLO}. In the case where the enable terminal is provided in the semiconductor device 1, the stop condition is also satisfied when the value of the enable signal changes from “1” to “0”.

In Step S9, the generation operation of the clock signal CLK by the oscillator 40 is stopped, and subsequently or simultaneously, the generation operation of the internal power supply voltage by the internal power supply circuit 30 is stopped. Due to the stoppage of the generation operation of the internal power supply voltage, the state of the semiconductor device 1 returns to the shutdown state. The stoppage of the generation operation of the internal power supply voltage by the internal power supply circuit 30 corresponds to the occurrence of transitioning to Step S1.

In Step S10, the diagnostic circuit 120 performs a predetermined error handling process. However, the entity executing the error handling process may be an error handling circuit (not shown) that is different from the diagnostic circuit 120 and provided in the semiconductor device 1. In the error handling process, an error signal is sent to the MPU 2. Additionally, in the error handling process, the diagnostic circuit 120 may store error flag data indicating that an abnormality has been detected in the logic circuit 110 in a memory (not shown) within the semiconductor device 1. The MPU 2 that receives the error signal can read out data in the memory by sending a command of reading out the data in the memory to the semiconductor device 1, and can understand the state of the semiconductor device 1 from the read data (including error flag data). In the case where the error handling process is performed, the functional operation is not executed. In the case of proceeding to Step S10, the flow returns to Step S1 by transitioning the semiconductor device 1 to the shutdown state.

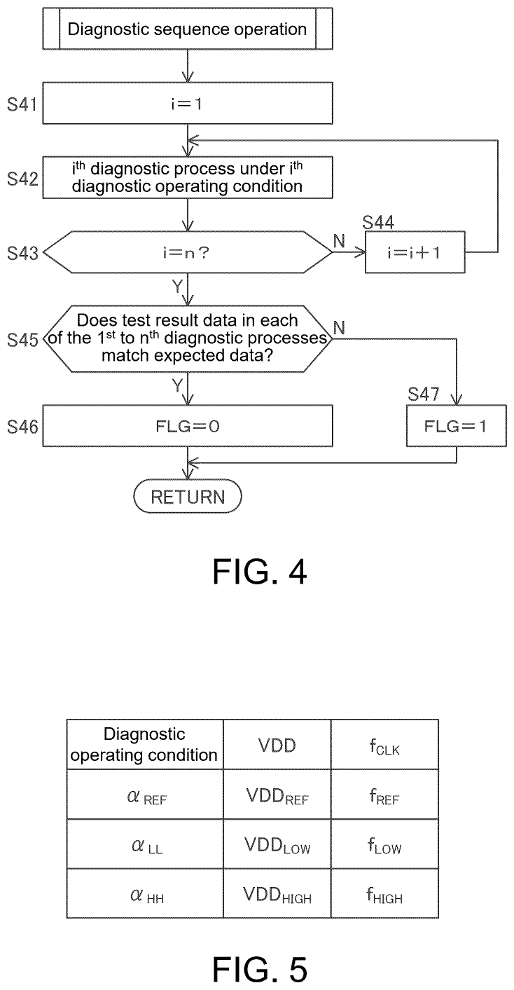

FIG. 4 shows a flowchart of the diagnostic sequence operation. In the diagnostic sequence operation, first, the process of Step S41 is executed. In Step S41, the diagnostic controller 121 assigns “1” to a variable i managed by the diagnostic controller 121. Then, the flow proceeds to Step S42.

In Step S42, the i^{th} diagnostic process is executed by the diagnostic circuit 120. The i^{th} diagnostic process is a diagnostic process performed in a state where the operating condition of the logic circuit 110 is set to the i^{th} diagnostic operating condition. In the case where i_{A} and i_{B} are natural numbers equal to and less than n and different from each other, between the i_{A}^{th} diagnostic operating condition and the i_{B}^{th} diagnostic operating condition, either the drive voltages VDD differ from each other, or the clock frequencies f_{CLK} differ from each other. Alternatively, each of the drive voltage VDD and the clock frequency f_{CLK} differs between the i_{A}^{th} diagnostic operating condition and the i_{B}^{th} diagnostic operating condition. The i^{th} diagnostic operating condition is set by the diagnostic controller 121 controlling the respective operating states of the internal power supply circuit 30 and the oscillator 40.

In the i^{th} diagnostic process, under the control of the diagnostic controller 121, the test pattern supply circuit 122 generates the test pattern and supplies the test pattern to the logic circuit 110. The test pattern supply circuit 122 supplies the test pattern to the logic circuit 110 in synchronization with the clock signal CLK. In the i^{th} diagnostic process, the logic circuit 110 generates the test result data by applying the digital signal process to the supplied test pattern. As described above, the digital signal process is executed in synchronization with the clock signal CLK. That is, the digital signal process is executed by using the sequential circuit SQC that operates in synchronization with the clock signal CLK. In the i^{th} diagnostic process, the logic circuit 110 outputs the test result data to the determination circuit 123 in synchronization with the clock signal CLK. In the i^{th} diagnostic process, the test result data is compared with the expected data by the determination circuit 123.

After Step S42, the flow advances to Step S43. In Step S43, the diagnostic controller 121 determines whether the value of the variable i matches the value of n. If “i=n” is established (Y in Step S43), the flow proceeds from Step S43 to Step S45. If “i=n” is not established (N in Step S43), the flow proceeds from Step S43 to Step S44. In Step S44, “1” is added to the variable i by the diagnostic controller 121, and then the flow returns to Step S42 to execute the process of Step S42 again. Therefore, by the time the flow proceeds to Step S45, the execution of the 1^{st} to n^{th} diagnostic processes has been completed.

In Step S45, the diagnostic controller 121 evaluates the comparison results of the determination circuit 123 in the 1^{st} to n^{th} diagnostic processes. In Step S45, it is determined whether the test result data matches the expected data in each of the 1^{st} to n^{th} diagnostic processes. The flow proceeds from Step S45 to S46 when the test result data matches the expected data in each of the 1^{st} to n^{th} diagnostic processes (Y in Step S45). If the test result data does not match the expected data in one or more diagnostic processes among the 1^{st} to n^{th} diagnostic processes (N in Step S45), the flow transitions from Step S45 to Step S47.

Therefore, for example, in the case where “n=3”, the flow transitions to Step S46 when the test result data matches the expected data in the first diagnostic process, the test result data matches the expected data in the second diagnostic process, and the test result data matches the expected data in the third diagnostic process; otherwise, the flow transitions to Step S47. The same applies in cases where the value of n is other than 3.

In Step S46, the diagnostic controller 121 sets a value “0” to the flag FLG. In Step S47, the diagnostic controller 121 sets a value “1” to the flag FLG. After completing the setting in Step S46 or S47, the diagnostic sequence operation ends.

“FLG=0” at the time point when the diagnostic sequence operation ends is the first result data derived by the diagnostic circuit 120. The first result data indicates that the logic circuit 110 is in a normal state and also indicates that the normal operation of the logic circuit 110 can be guaranteed even if there are some fluctuations in the drive voltage VDD or clock frequency f_{CLK}. At the end of the diagnostic sequence operation, “FLG=1” is the second result data derived by the diagnostic circuit 120. The second result data indicates that the logic circuit 110 is in an abnormal state, or that a normal operation of the logic circuit 110 cannot be guaranteed if fluctuations occur in the drive voltage VDD or the clock frequency f_{CLK}. While each individual diagnostic process can be said to diagnose whether the logic circuit 110 is in a state capable of normal operation, the diagnostic circuit 120 according to the embodiment tests the operation of the logic circuit 110 through the diagnostic sequence operation including multiple diagnostic processes, thereby diagnosing whether the logic circuit 110 is in a state capable of normal operation.

While differing from the flow of the flowchart in FIG. 4, after the start of the diagnostic sequence operation, in the case where it is detected by the determination circuit 123 that the test result data does not match the expected data in the i^{th} diagnostic process under the condition “i<n”, the diagnostic controller 121 may set the value “1” to the flag FLG and end the diagnostic sequence operation at such detection time point.

In many reference semiconductor devices that differ from the semiconductor device 1, the following reference method is often adopted. In the reference method, BIST is executed in the state where the logic circuit is executed under a typical single operating condition (typical operating condition), thereby diagnosing whether there is a failure in the logic circuit. However, after the BIST is completed and the functional operation using the logic circuit begins, the drive voltage or the clock frequency supplied to the logic circuit may fluctuate from the single operating condition due to influences such as noise. In the reference method, it cannot be guaranteed that the logic circuit can maintain normal operation against such fluctuations.

Comparatively, in the semiconductor device 1 according to the embodiment, the first to n^{th} diagnostic processes are performed while the operating conditions of the logic circuit 110 are changed, and the quality of the logic circuit 110 is determined based on the results (the first result data or the second result data is derived) of the diagnostic processes. Therefore, after the first result data is derived and the functional operation begins, the normal operation of the logic circuit 110 is guaranteed (or highly likely to be guaranteed) even if there are some fluctuations in the drive voltage VDD or the clock frequency f_{CLK}. Thus, it is possible to maintain high reliability in the semiconductor device 1.

In the following, among multiple examples, several specific operation examples, application technologies, modified technologies, etc., related to the semiconductor device 1 will be described. The matters described above in the embodiment are applied to each of the following examples unless specifically stated otherwise and without contradiction. In each example, if there are matters that contradict the above description, the description in each example may take precedence. Also, as long as there is no contradiction, matters described in any example among the multiple examples shown below can be applied to any other example (i.e., it is possible to combine any two or more examples among the multiple examples).

### First Example

The first example will be described. In the first example, “n=3”. The first to third diagnostic operating conditions are formed by diagnostic operating conditions α_{REF}, α_{LL}, and α_{HH}. For example, the first, second, and third diagnostic operating conditions may be diagnostic operating conditions α_{REF}, α_{LL}, α_{HH}, respectively, or may be diagnostic operating conditions α_{REF}, α_{HH}, α_{LL}, or may be diagnostic operating conditions α_{LL}, α_{REF}, α_{HH}, or may be diagnostic operating conditions α_{HH}, α_{REF}, α_{LL}. Besides, the assignment relationship between the diagnostic operating conditions α_{REF}, α_{LL}, and α_{HH} and the first to third diagnostic operating conditions is arbitrary.

In the case where the first, second, and third diagnostic operating conditions are assigned to the diagnostic operating conditions α_{REF}, α_{LL}, and α_{HH} respectively, in the diagnostic sequence operation of FIG. 4, the first diagnostic process according to the diagnostic operating condition α_{REF} is executed first, the second diagnostic process according to the diagnostic operating condition α_{LL} is executed second, and the third diagnostic process according to the diagnostic operating condition α_{HH} is executed third. In the case where the first, second, and third diagnostic operating conditions are assigned to the diagnostic operating conditions α_{HH}, α_{REF}, and α_{LL} respectively, in the diagnostic sequence operation of FIG. 4, the first diagnostic process according to the diagnostic operating condition α_{HH} is executed first, the second diagnostic process according to the diagnostic operating condition α_{REF} is executed second, and the third diagnostic process according to the diagnostic operating condition α_{LL} is executed third. The same applies in cases where the assignment relationship between the diagnostic operating conditions α_{REF}, α_{LL}, and α_{HH} and the first to third diagnostic operating conditions differs from each of the above cases.

FIG. 5 shows the details of the diagnostic operating conditions α_{REF}, α_{LL}, and α_{HH}. The diagnostic operating condition α_{REF} is the same as the operating condition of the logic circuit 110 in the normal operating state (see Step S6 in FIG. 3). That is, in the diagnostic operating condition α_{REF}, the drive voltage VDD matches the reference voltage VDD_{REF}, and the clock frequency f_{CLK} matches the reference frequency f_{REF}. In the diagnostic operating condition α_{LL}, the drive voltage VDD matches a low side voltage VDD_{LOW}, and the clock frequency f_{CLK} matches a low side frequency f_{LOW}. In the diagnostic operating condition α_{HH}, the drive voltage VDD matches a high side voltage VDD_{HIGH}, and the clock frequency f_{CLK} matches a high side frequency f_{HIGH}.

The low side voltage VDD_{LOW}, the reference voltage VDD_{REF}, and the high side voltage VDD_{HIGH} are three positive predetermined voltages that satisfy “0<VDD_{LOW}<VDD_{REF}<VDD_{HIGH}”, and are, for example, 1.3V (volts), 1.5V, and 1.7V respectively. The low side frequency f_{LOW}, the reference frequency f_{REF}, and the high side frequency f_{HIGH} are three predetermined frequencies that satisfy “0<f_{LOW}<f_{REF}<f_{HIGH}”, and are, for example, 0.8 MHz (megahertz), 1.0 MHz, and 1.2 MHz respectively. The diagnostic controller 121 can variously change the drive voltage VDD by controlling the operating state of the internal power supply circuit 30. The diagnostic controller 121 can variously change the clock frequency f_{CLK} by controlling the operating state of the oscillator 40.

Since the diagnostic operating condition α_{REF} is the same as the operating condition of the logic circuit 110 in the normal operating state, by executing the diagnostic process with the diagnostic operating condition α_{REF}, it is possible to effectively determine whether the logic circuit 110 can operate normally in the normal operating state.

A decrease in the clock frequency f_{CLK} directly leads to a decrease in the operating speed of the logic circuit 110, and a decrease in the drive voltage VDD also acts in a direction of decreasing the operating speed of the logic circuit 110. Therefore, in the diagnostic operating condition α_{LL}, the operating speed of the logic circuit 110 decreases due to the decrease in the drive voltage VDD and the decrease in the clock frequency f_{CLK} compared to those in the diagnostic operating condition α_{REF}. By executing the diagnostic process according to the diagnostic operating condition α_{LL}, it is possible to evaluate whether the normal operation of the logic circuit 110 (and therefore the normal operation of the functional operation) is guaranteed even if the drive voltage VDD and the clock frequency f_{CLK} decrease in a direction that reduces the operating speed of the logic circuit 110 during the execution period of the functional operation.

An increase in the clock frequency f_{CLK} directly leads to an increase in the operating speed of the logic circuit 110, and an increase in the drive voltage VDD also acts in a direction of increasing the operating speed of the logic circuit 110. Therefore, in the diagnostic operating condition α_{HH}, the operating speed of the logic circuit 110 increases due to the increase in the drive voltage VDD and the increase in the clock frequency f_{CLK} compared to those in the diagnostic operating condition α_{REF}. By executing the diagnostic process according to the diagnostic operating condition α_{HH}, it is possible to evaluate whether the normal operation of the logic circuit 110 (and therefore the normal operation of the functional operation) is guaranteed even if the drive voltage VDD and the clock frequency f_{CLK} increase in a direction that increases the operating speed of the logic circuit 110 during the execution period of the functional operation.

### Second Example

The second example will be described. In the second example, “n=5”. The first to fifth diagnostic operating conditions are formed by the diagnostic operating conditions α_{REF}, α_{LL}, α_{HH}, α_{LH} and α_{HL}. For example, the first, second, third, fourth, and fifth diagnostic operating conditions may be diagnostic operating conditions α_{REF}, α_{LL}, α_{HH}, α_{LH} and α_{HL}, respectively, or may be diagnostic operating conditions α_{REF}, α_{HH}, α_{LL}, α_{HL} and α_{LH}, or may be diagnostic operating conditions α_{LL}, α_{REF}, α_{LH}, α_{LH} and α_{HL}, or may be diagnostic operating conditions α_{HH}, α_{REF}, α_{LL}, α_{HL} and α_{LH}. Besides, the assignment relationship among the diagnostic operating conditions α_{REF}, α_{LL}, α_{HH}, α_{LH} and α_{HL} and the first to fifth diagnostic operating conditions is arbitrary.

In the case where the first, second, third, fourth, and fifth diagnostic operating conditions are assigned to the diagnostic operating conditions α_{REF}, α_{LL}, α_{HH}, α_{LH}, and α_{HL} respectively, in the diagnostic sequence operation of FIG. 4, the first diagnostic process according to the diagnostic operating condition α_{REF} is executed first, followed by the second, third, fourth, and fifth diagnostic processes according to the diagnostic operating conditions α_{LL}, α_{HH}, α_{LH}, and α_{HL} in such order. In the case where the first, second, third, fourth, and fifth diagnostic operating conditions are assigned to the diagnostic operating conditions α_{HH}, α_{REF}, α_{LL}, α_{HL}, and α_{LH} respectively, in the diagnostic sequence operation of FIG. 4, the first diagnostic process according to the diagnostic operating condition α_{HH} is executed first, followed by the second, third, fourth, and fifth diagnostic processes according to the diagnostic operating conditions α_{REF}, α_{LL}, α_{HL}, and α_{LH} in such order. The same applies in cases where the assignment relationship between the diagnostic operating conditions α_{REF}, α_{LL}, α_{HH}, α_{LH}, and α_{HL} and the first to fifth diagnostic operating conditions differs from each of the above cases.

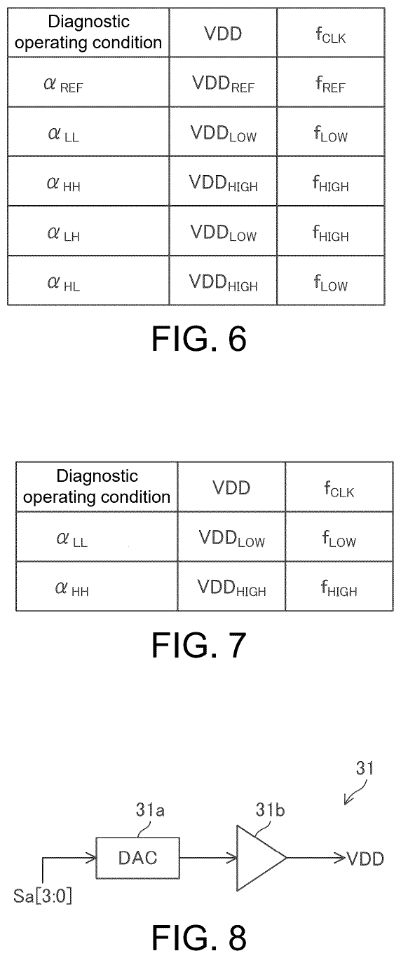

FIG. 6 shows the details of the diagnostic operating conditions α_{REF}, α_{LL}, α_{HH}, α_{LH}, and α_{HL}. Among the five operating conditions, the contents of the diagnostic operating conditions α_{REF}, α_{LL}, and α_{HL} are as described in the first example. In the diagnostic operating condition α_{LH}, the drive voltage VDD matches the low side voltage VDD_{LOW}, and the clock frequency f_{CLK} matches the high side frequency f_{HIGH}. In the diagnostic operating condition α_{HL}, the drive voltage VDD matches the high side voltage VDD_{HIGH}, and the clock frequency f_{CLK} matches the low side frequency f_{LOW}. As described in the first example, “0<VDD_{LOW}<VDD_{REF}<VDD_{HIGH}” and “0<f_{LOW}<f_{REF}<f_{HIGH}” are satisfied.

The significance of executing the diagnostic process according to the diagnostic operating conditions α_{REF}, α_{LL}, and α_{HH} is as described in the first example. In the second example, with the addition of the diagnostic processes under two more operating conditions, further improvement in reliability is expected. However, as the value of n increases, the time required to execute the diagnostic sequence operation increases, so in the case where priority is given to reducing the execution time of the diagnostic sequence operation, the first example is more preferable than the second example.

### Third Example

The third example will be described. In the third example, “n=2”. The first and second diagnostic operating conditions are formed by the diagnostic operating conditions α_{LL} and α_{HH}. At this time, the first diagnostic operating condition may be the diagnostic operating condition α_{LL} and the second diagnostic operating condition may be the diagnostic operating condition α_{HH}, or the first diagnostic operating condition may be the diagnostic operating condition α_{HH} and the second diagnostic operating condition may be diagnostic operating condition α_{LL}.

In the case where the first and second diagnostic operating conditions are assigned to the diagnostic operating conditions α_{LL} and α_{HH} respectively, in the diagnostic sequence operation of FIG. 4, the first diagnostic process according to the diagnostic operating condition α_{LL} is executed first, and then the second diagnostic process according to the diagnostic operating condition α_{HH} is executed second. In the case where the first and second diagnostic operating conditions are assigned to the diagnostic operating conditions α_{HH} and α_{LL} respectively, in the diagnostic sequence operation of FIG. 4, the first diagnostic process according to the diagnostic operating condition α_{HH} is executed first, and then the second diagnostic process according to the diagnostic operating condition α_{LL} is executed second.

FIG. 7 shows the details of the diagnostic operating conditions α_{LL} and α_{HH}. The contents of the two diagnostic operating conditions α_{LL} and α_{HH} are as described in the first example.

The significance of executing the diagnostic process according to the diagnostic operating conditions α_{LL} and α_{HH} is as described in the first example. Compared to the diagnostic operating condition α_{REF}, under the diagnostic operating condition α_{LL}, the operating speed of the logic circuit 110 shifts toward the decreasing direction, and under the diagnostic operating condition α_{HH}, the operating speed of the logic circuit 110 shifts in the increasing direction. Therefore, if it is confirmed that normal operation of the logic circuit 110 is guaranteed by executing the diagnostic processes under the diagnostic operating conditions α_{LL} and α_{HH}, normal operation of the logic circuit 110 is expected to be guaranteed in the normal operating state. In the second example, a reduction in execution time of the diagnostic sequence operation is achieved compared to the first example. However, considering that the logic circuit 110 basically operates under the same operating conditions as the diagnostic operating condition α_{REF} in the normal operating state, it can also be said that it is preferable to perform the diagnostic process under the diagnostic operating condition α_{REF} as well.

### Fourth Example

The fourth example will be described. If “n≥2” and the first to n^{th} diagnostic operating conditions are different from each other, the first to n^{th} diagnostic operating conditions are not limited to those described in the first to third examples. For example, in the case where “n=2”, the first and second diagnostic operating conditions may be the diagnostic operating conditions α_{REF} and α_{HH}, or the diagnostic operating conditions α_{REF} and α_{LL}. It is also possible to set “n≥6”.

### Fifth Example

The fifth example will be described. The diagnostic controller 121 according to the fifth example fixes the clock frequency f_{CLK} to the reference frequency f_{REF} in the first to n^{th} diagnostic processes, and varies only the drive voltage VDD. In the case where “n=3”, among the first to third diagnostic operating conditions, one of the diagnostic operating conditions may be set as “VDD=VDD_{REF}”, another diagnostic operating condition may be set as “VDD=VDD_{LL}”, and yet another diagnostic operating condition may be set as “VDD=VDD_{HH}”.

In the case where “n=2”, between the first and second diagnostic operating conditions, one of the diagnostic operating conditions may be set as “VDD=VDD_{LL}”, and the other diagnostic operating condition may be set as “VDD=VDD_{HH}”. Alternatively, in the case where “n=2”, between the first and second diagnostic operating conditions, one of the diagnostic operating conditions may be set as “VDD=VDD_{REF}”, and the other diagnostic operating condition may be set as “VDD=VDD_{LL}” or “VDD=VDD_{HH}”.

According to the diagnostic process of the fifth example, it is possible to evaluate whether the normal operation of the logic circuit 110 (and therefore the normal operation of the functional operation) is guaranteed even if the drive voltage VDD fluctuates during the execution period of the functional operation.

### Sixth Example

The sixth example will be described. The diagnostic controller 121 according to the sixth example fixes the drive voltage VDD to the reference voltage VDD_{REF} in the first to n^{th} diagnostic processes, and varies only the clock frequency f_{CLK}. In the case where “n=3”, among the first to third diagnostic operating conditions, one of the diagnostic operating conditions may be set as “f_{CLK}=f_{REF}”, another diagnostic operating condition may be set as “f_{CLK}=f_{LOW}”, and yet another diagnostic operating condition may be set as “f_{CLK}=f_{HIGH}”.

In the case where “n=2”, between the first and second diagnostic operating conditions, one of the diagnostic operating conditions may be set as “f_{CLK}=f_{LOW}”, and the other diagnostic operating condition may be set as “f_{CLK}=f_{HIGH}”. Alternatively, in the case where “n=2”, between the first and second diagnostic operating conditions, one of the diagnostic operating conditions may be set as “f_{CLK}=f_{REF}”, and the other diagnostic operating condition may be set as “f_{CLK}=f_{LOW}” or “f_{CLK}=f_{HIGH}”.

According to the diagnostic process of the sixth example, it is possible to evaluate whether the normal operation of the logic circuit 110 (and therefore the normal operation of the functional operation) is guaranteed even if the clock frequency f_{CLK} fluctuates during the execution period of the functional operation.

### Seventh Example

The seventh example will be described. FIG. 8 shows the configuration of the drive voltage generation circuit 31 that generates the drive voltage VDD. The drive voltage generation circuit 31 can be provided in the internal power supply circuit 30. The drive voltage generation circuit 31 includes a DAC 31a and a buffer circuit 31b. The DAC 31a and the buffer circuit 31b are driven based on the power supply voltage V_{PW}.

A control signal Sa[3:0] is supplied from the digital block 10 to the DAC 31a. The control signal Sa[3:0] may be a signal output by the logic circuit 110. However, during the execution period of the diagnostic sequence operation, the content of the control signal Sa[3:0] is determined by the diagnostic controller 121. The control signal Sa[3:0] is a digital signal of multiple bits, and here it is assumed to be a 4-bit digital signal.

The DAC 31a is a digital/analog converter that converts the digital control signal Sa[3:0] to an analog signal and outputs the analog signal. The buffer circuit 31b generates the drive voltage VDD by performing impedance conversion of the output signal from the DAC 31a. That is, the buffer circuit 31b outputs the analog signal output from the DAC 31a at a sufficiently low impedance. The output signal of the buffer circuit 31b functions as the drive voltage VDD. Therefore, the voltage value of the output signal of the DAC 31a is equal to the value of the drive voltage VDD. The configuration of the drive voltage generation circuit 31 shown in FIG. 8 is merely an example. Any drive voltage generation circuit that generates the drive voltage VDD in an adjustable manner can be provided in the internal power supply circuit 30.

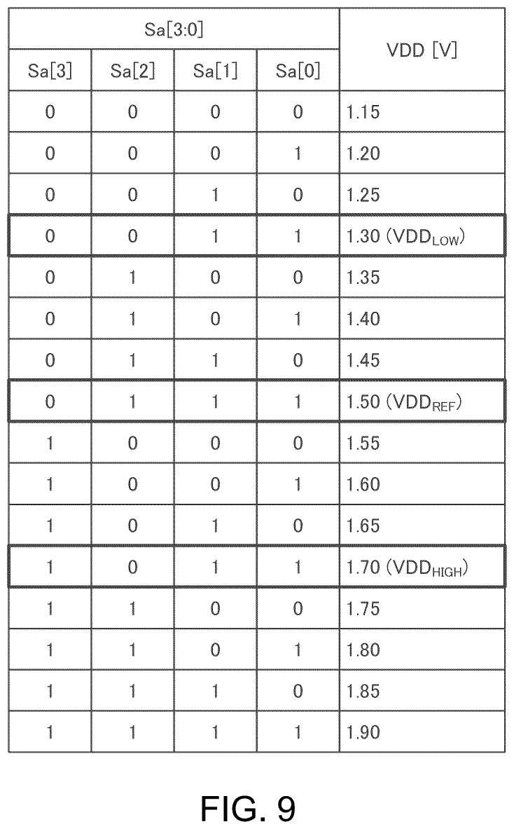

FIG. 9 shows the relationship between the control signal Sa[3:0] and the drive voltage VDD. The control signal Sa[3:0] is formed by signals Sa[3] to Sa[0]. Each of the signals Sa[3] to Sa[0] is a 1-bit digital signal and has a value of “0” or “1”. For any integer i, the signal Sa[i+1] has a value of a higher bit than the signal Sa[i]. The value of the control signal Sa[3:0] expressed in decimal notation is represented by a symbol “VAL_Sa[3:0]”. Thus, “VAL_Sa[3:0]=2³×Sa[3]+2²×Sa[2]+2¹×Sa[1]+2°×Sa[0]”. The conversion process in the DAC 31a is performed so that the conversion formula “VDD=0.05×VAL_Sa[3:0]+1.15” is satisfied (the unit in the conversion formula is volts).

Also, here, it is assumed that the reference voltage VDD_{REF} is 1.50V, the low side voltage VDD_{LOW} is 1.30V, and the high side voltage VDD_{HIGH} is 1.70V. Therefore, when the control signal Sa[3:0] satisfying the following equation (1a) is supplied to the DAC 31a, the drive voltage VDD matches the reference voltage VDD_{REF}; when the control signal Sa[3:0] satisfying the following equation (1b) is supplied to the DAC 31a, the drive voltage VDD matches the low side voltage VDD_{LOW}; and when the control signal Sa[3:0] satisfying the following equation (1c) is supplied to the DAC 31a, the drive voltage VDD matches the high side voltage VDD_{HIGH}.

$$( Sa [ 3 ] , Sa [ 2 ] , Sa [ 1 ] , Sa [ 0 ] ) = ( 0 , 1 , 1 , 1 ) \qquad ( 1 a )$$

$$( Sa [ 3 ] , Sa [ 2 ] , Sa [ 1 ] , Sa [ 0 ] ) = ( 0 , 0 , 1 , 1 ) \qquad ( 1 b )$$

$$( Sa [ 3 ] , Sa [ 2 ] , Sa [ 1 ] , Sa [ 0 ] ) = ( 1 , 0 , 1 , 1 ) \qquad ( 1 c )$$

Therefore, in the normal operating state, the digital block 10 supplies the control signal Sa[3:0] satisfying the equation (1a) to the DAC 31a. During the execution period of the diagnostic sequence operation, the diagnostic controller 121 may supply the control signal Sa[3:0] satisfying any of the equations (1a), (1b), and (1c) to the DAC 31a according to the drive voltage VDD as required.

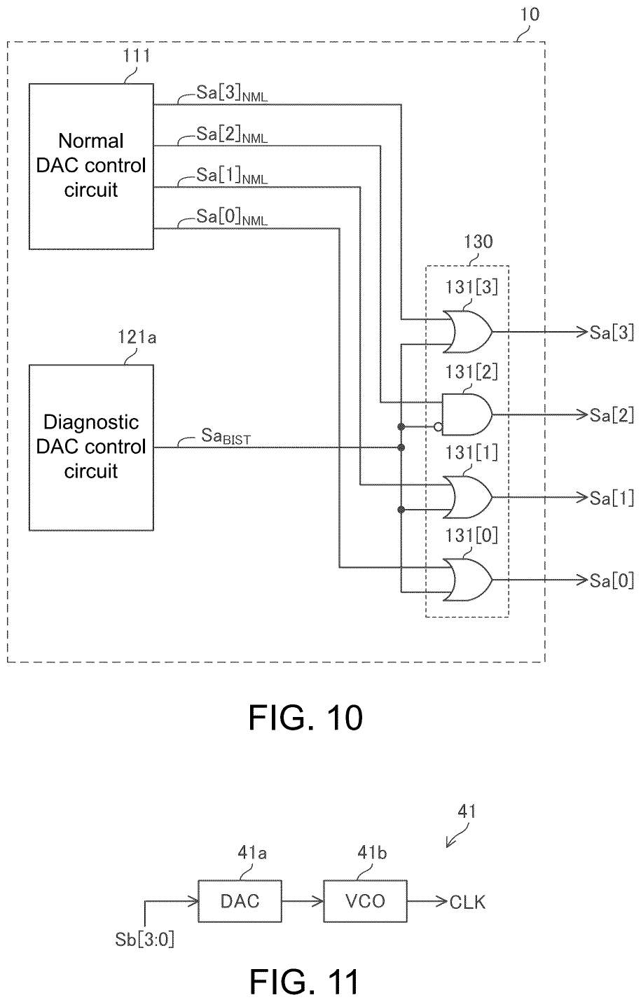

FIG. 10 shows an example of a circuit configuration for setting the drive voltage VDD to the reference voltage VDD_{REF} in the normal operating state and setting the drive voltage VDD to the high side voltage VDD_{HIGH} in the diagnostic process. In the digital block 10 according to the example of FIG. 10, a normal DAC control circuit 111, a diagnostic DAC control circuit 121a, and a control signal output circuit 130 are provided. The normal DAC control circuit 111 and the control signal output circuit 130 are provided in the logic circuit 110 (see FIG. 2). However, the control signal output circuit 130 may be considered as being provided outside the logic circuit 110. The diagnostic DAC control circuit 121a is provided in the diagnostic controller 121. The control signal output circuit 130 includes circuits 131[3], 131[1], and 131[0], which are 2-input logical OR circuits, and a circuit 131[2], which is a 2-input logical AND circuit. The circuits 131[3] to 131[0] each include first and second input terminals and an output terminal. For each integer i satisfying “0≤i≤3”, the signal Sa[i] is output from the output terminal of the circuit 131[i].

The normal DAC control circuit 111 supplies signals Sa[3]_{NML}, Sa[2]_{NML}, Sa[1]_{NML}, Sa[0] NML to the first input terminals of the circuits 131[3], 131[2], 131[1], 131[0], respectively. The diagnostic DAC control circuit 121a commonly supplies a signal Sa_{BIST} to the second input terminals of the circuits 131[3] to 131[0], respectively. The signals Sa[3]_{NML} to Sa[0]_{NML} and Sa_{BIST} are each a 1-bit digital signal having a value of “0” or “1”.

The circuit 131[3] outputs the signal Sa[3] of “1” in the case where at least one of the signals Sa[3]_{NML} and Sa_{BIST} has a value of “1”, and outputs the signal Sa[3] of “0” in the case where both signals Sa[3]_{NML} and Sa_{BIST} have a value of “0”. The circuit 131[2] outputs a signal Sa[2] of “1” only in the case where the signal Sa[2]_{NML} has a value of “1” and the signal Sa_{BIST} has a value of “0”, and outputs a signal Sa[2] of “0” in other cases. The circuit 131[1] outputs the signal Sa[1] of “1” in the case where at least one of the signals Sa[1]_{NML} and Sa_{BIST} has a value of “1”, and outputs the signal Sa[1] of “0” in the case where both signals Sa[1]_{NML} and Sa_{BIST} have a value of “0”. The circuit 131[0] outputs the signal Sa[0] of “1” in the case where at least one of the signals Sa[0]_{NML} and Sa_{BIST} has a value of “1”, and outputs the signal Sa[0] of “0” in the case where both signals Sa[0]_{NML} and Sa_{BIST} have a value of “0”.

The normal DAC control circuit 111 is a circuit that functions significantly only in the normal operating state. In the normal operating state, the normal DAC control circuit 111 outputs the signals Sa[3]_{NML} to Sa[0] mW satisfying “(Sa[3]_{NML},Sa[2]_{NML},Sa[1]_{NML},Sa[0]_{NML})=(0,1,1,1)” to the control signal output circuit 130. On the other hand, the diagnostic DAC control circuit 121a outputs the signal Sa_{BIST} Of “1” to the control signal output circuit 130 during the period in which the drive voltage VDD should be set to the high side voltage VDD_{HIGH} in the diagnostic sequence operation. The diagnostic DAC control circuit 121a fixes the value of the signal Sa_{BIST} to “0” in the normal operating state.

As a result, the output signals Sa[3] to Sa[0] of the control signal output circuit 130 in the normal operating state are determined only by the signals Sa[3]_{NML} to Sa[0]_{NML}. In the normal operating state, “(Sa[3]_{NML},Sa[2]_{NML},Sa[1]_{NML},Sa[0]_{NML})=(Sa[3],Sa[2],Sa[1],Sa[0])=(0,1,1,1)” so “VDD=VDD_{REF}” (see also to FIG. 9). Meanwhile, during the period where “Sa_{BIST}=1”, regardless of the signals Sa[3]_{NML} to Sa[0]_{NML}, the output signals Sa[3] to Sa[0] of the control signal output circuit 130 are fixed at “(Sa[3],Sa[2],Sa[1],Sa[0])=(1,0,1,1)” according to the logic of the control signal output circuit 130. Therefore, during the period where “Sa_{BIST}=1”, “VDD=VDD_{HIGH}” (see also to FIG. 9).

In the case where the normal DAC control circuit 111 is a component of the logic circuit 110, the output signals of the circuit 111 may vary in various ways during the execution period of the diagnostic process, but if configured as shown in FIG. 10, the values of signals Sa[3] to Sa[0] can be fixed at desired values regardless of the variation of the output signals of the circuit 111.

FIG. 10 shows the control signal output circuit (130) for implementing a diagnostic process that satisfies “VDD=VDD_{HIGH}”, but a control signal output circuit for implementing a diagnostic process that satisfies “VDD=VDD_{LOW}” and a control signal output circuit for implementing a diagnostic process that satisfies “VDD=VDD_{REF}” can also be formed by changing the logic configuration of the control signal output circuit from that shown in FIG. 10. By combining the control signal output circuit for implementing a diagnostic process that satisfies “VDD=VDD_{HIGH}”, the control signal output circuit for implementing a diagnostic process that satisfies “VDD=VDD_{LOW}”, and the control signal output circuit for implementing a diagnostic process that satisfies “VDD=VDD_{REF}”, any of the voltages VDD_{HIGH}, VDD_{LOW}, and VDD_{REF} can be selectively set with respect to the drive voltage VDD in the diagnostic sequence operation.

### Eighth Example

The eighth example will be described. FIG. 11 shows the configuration of the oscillator 41. The oscillator 41 is an example of the oscillator 40 described above (see FIG. 2). The oscillator 41 includes a DAC 41a and a VCO 41b. The DAC 41a and VCO 41b are driven based on the power supply voltage V_{PW}.

A control signal Sb[3:0] is supplied from the digital block 10 to the DAC 41a. The control signal Sb[3:0] may be a signal output by the logic circuit 110. However, during the execution period of the diagnostic sequence operation, the content of the control signal Sb[3:0] is determined by the diagnostic controller 121. The control signal Sb[3:0] is a digital signal of multiple bits, and here it is assumed to be a 4-bit digital signal.

The DAC 41a is a digital/analog converter that converts the digital control signal Sb[3:0] to an analog signal and outputs the analog signal. The VCO 41b is a voltage-controlled oscillator that generates and outputs a rectangular wave signal with a frequency corresponding to the output signal of the DAC 41a. The rectangular wave signal output from the VCO 41b is used as the clock signal CLK. Therefore, the frequency of the rectangular wave signal output from the VCO 41b is the clock frequency f_{CLK}. The VCO 41b increases the clock frequency f_{CLK} as the voltage value of the output signal from the DAC 41a increases, and decreases the clock frequency f_{CLK} as the voltage value of the output signal from the DAC 41a decreases.

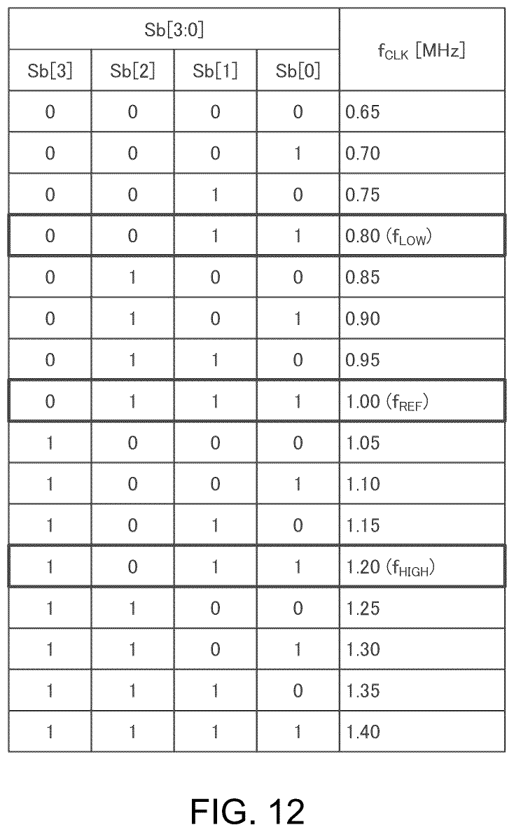

FIG. 12 shows the relationship between the control signal Sb[3:0] and the clock frequency f_{CLK}. The control signal Sb[3:0] is formed by signals Sb[3] to Sb[0]. Each of the signals Sb[3] to Sb[0] is a 1-bit digital signal and has a value of “0” or “1”. For any integer i, the signal Sb[i+1] has a value of a higher bit than the signal Sb[i]. The value of the control signal Sb[3:0] expressed in decimal notation is represented by a symbol “VAL_Sb[3:0]”. Thus, “VAL_Sb[3:0]=2³×Sb[3]+2²×Sb[2]+2¹×Sb[1]+2°×Sb[0]”. In addition, the DAC 41a and VCO 41b are formed so that the conversion formula “f_{CLK}=0.05×VAL_Sb[3:0]+0.65” is satisfied (the unit in the conversion formula is MHz).

In addition, here, it is assumed that the reference frequency f_{REF} is 1.00 MHz, the low side frequency f_{LOW} is 0.80 MHz, and the high side frequency f_{HIGH} is 1.20 MHz. Therefore, when the control signal Sb[3:0] satisfying the following equation (2a) is supplied to the DAC 41a, the clock frequency f_{CLK} matches the reference frequency f_{REF}; when the control signal Sb[3:0] satisfying the following equation (2b) is supplied to the DAC 41a, the clock frequency f_{CLK} matches the low side frequency f_{LOW}; and when the control signal Sb[3:0] satisfying the following equation (2c) is supplied to the DAC 41a, the clock frequency f_{CLK} matches the high side frequency f_{HIGH}.

$$( Sb [ 3 ] , Sb [ 2 ] , Sb [ 1 ] , Sb [ 0 ] ) = ( 0 , 1 , 1 , 1 ) \qquad ( 2 a )$$

$$( Sb [ 3 ] , Sb [ 2 ] , Sb [ 1 ] , Sb [ 0 ] ) = ( 0 , 0 , 1 , 1 ) \qquad ( 2 b )$$

$$( Sb [ 3 ] , Sb [ 2 ] , Sb [ 1 ] , Sb [ 0 ] ) = ( 1 , 0 , 1 , 1 ) \qquad ( 2 c )$$

Therefore, in the normal operating state, the digital block 10 supplies the control signal Sb[3:0] satisfying the equation (2a) to the DAC 41a. During the execution period of the diagnostic sequence operation, the diagnostic controller 121 may supply the control signal Sb[3:0] satisfying any of the equations (2a), (2b), and (2c) to the DAC 41a according to the clock frequency f_{CLK} as required.

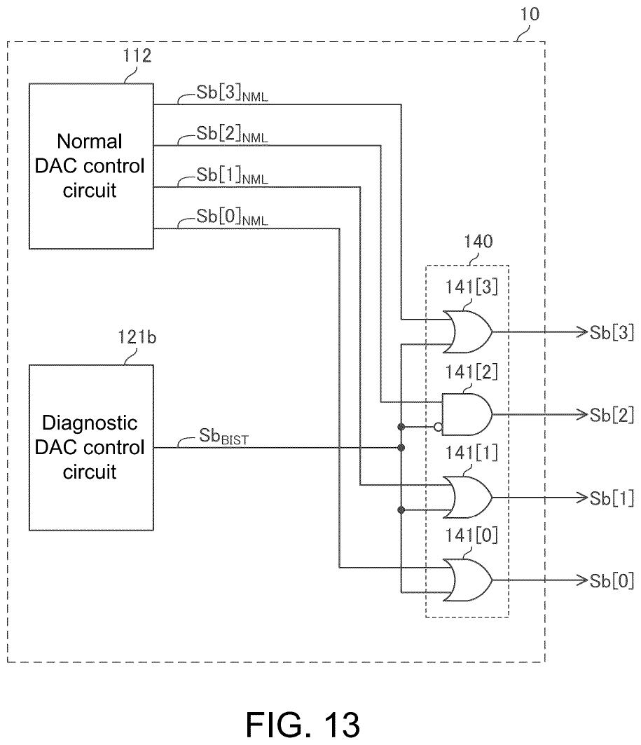

FIG. 13 shows an example of a circuit configuration for setting the clock frequency f_{CLK} to the reference frequency f_{REF} in the normal operating state and setting the clock frequency f_{CLK} to the high side frequency f_{HIGH} in the diagnostic process. In the digital block 13 according to the example of FIG. 10, a normal DAC control circuit 112, a diagnostic DAC control circuit 121b, and a control signal output circuit 140 are provided. The normal DAC control circuit 112 and the control signal output circuit 140 are provided in the logic circuit 110 (see FIG. 2). However, the control signal output circuit 140 may be considered as being provided outside the logic circuit 110. The diagnostic DAC control circuit 121b is provided in the diagnostic controller 121. The control signal output circuit 140 includes circuits 141[3], 141[1], and 141[0], which are 2-input logical OR circuits, and a circuit 141[2], which is a 2-input logical AND circuit. The circuits 141[3] to 141[0] each include first and second input terminals and an output terminal. For each integer i satisfying “0≤i≤3”, the signal Sb[i] is output from the output terminal of the circuit 141[i].

The normal DAC control circuit 112 supplies signals Sb[3]_{NML}, Sb[2]_{NML}, Sb[1]_{NML}, Sb[0]_{NML} to the first input terminals of the circuits 141[3], 141[2], 141[1], 141[0], respectively. The diagnostic DAC control circuit 121b commonly supplies a signal Sb_{BIST} to the second input terminals of the circuits 141[3] to 141[0], respectively. The signals Sb[3]_{NML} to Sb[0]_{NML} and Sb_{BIST} are each a 1-bit digital signal having a value of “0” or “1”.

The circuit 141[3] outputs the signal Sb[3] of “1” in the case where at least one of the signals Sb[3]_{NML} and Sb_{BIST} has a value of “1”, and outputs the signal Sb[3] of “0” in the case where both signals Sb[³]_{NML} and Sb_{BIST} have a value of “0”. The circuit 141[2] outputs a signal Sb[2] of “1” only in the case where the signal Sb[²]_{NML} has a value of “1” and the signal Sb_{BI}ST has a value of “0”, and outputs a signal Sb[2] of “0” in other cases. The circuit 141[1] outputs the signal Sb[1] of “1” in the case where at least one of the signals Sb[1]_{NML} and Sb_{BIST} has a value of “1”, and outputs the signal Sb[1] of “0” in the case where both signals Sb[1]_{NML} and Sb_{BIST} have a value of “0”. The circuit 141[0] outputs the signal Sb[0] of “1” in the case where at least one of the signals Sb[0]_{NML} and Sb_{BI}ST has a value of “1”, and outputs the signal Sb[0] of “0” in the case where both signals Sb[0]_{NML} and Sb_{BI}ST have a value of “0”.

The normal DAC control circuit 112 is a circuit that functions significantly only in the normal operating state. In the normal operating state, the normal DAC control circuit 112 outputs the signals Sb[3] mW to Sb[0] mW satisfying “(Sa[3]_{NML},Sa[2]_{NML},Sa[1]_{NML},Sa[0]_{NML})=(0,1,1,1)” to the control signal output circuit 140. On the other hand, the diagnostic DAC control circuit 121b outputs the signal Sb_{BI}ST of “1” to the control signal output circuit 140 during the period in which the clock frequency f_{CLK} should be set to the high side frequency f_{HIGH} in the diagnostic sequence operation. The diagnostic DAC control circuit 121b fixes the value of the signal Sb_{BIST} to “0” in the normal operating state.

As a result, the output signals Sb[3] to Sb[0] of the control signal output circuit 140 in the normal operating state are determined only by the signals Sb[3]_{NML} to Sb[0]_{NML}. In the normal operating state, “(Sb[3]_{NML},Sb[2]_{NML},Sb[1]_{NML},Sb[0]_{ML})=(Sb[3],Sb[2],Sb[1],Sb[0])=(0,1,1,1)” SO “f_{CLK}=f_{REF}” (see also to FIG. 12). Meanwhile, during the period where “Sb_{BIST}=1”, regardless of the signals Sb[3]_{NML} to Sb[0]_{NML}, the output signals Sb[3] to Sb[0] of the control signal output circuit 140 are fixed at “(Sb[3],Sb[2],Sb[1],Sb[0])=(1,0,1,1)” according to the logic of the control signal output circuit 140. Therefore, during the period where “Sb_{BIST}=1”, “f_{CLK}=f_{HIGH}” (see also to FIG. 12).

In the case where the normal DAC control circuit 112 is a component of the logic circuit 110, the output signals of the circuit 112 may vary in various ways during the execution period of the diagnostic process, but if configured as shown in FIG. 13, the values of the signals Sb[3] to Sb[0] can be fixed at desired values regardless of the variation of the output signals of the circuit 112.

FIG. 13 shows the control signal output circuit (140) for implementing a diagnostic process that satisfies “f_{CLK}=f_{HIGH}”, but a control signal output circuit for implementing the diagnostic process that satisfies “f_{CLK}=f_{LOW}” and a control signal output circuit for implementing a diagnostic process that satisfies “f_{CLK}=REF” can also be formed by changing the logic configuration of the control signal output circuit from that shown in FIG. 13. By combining the control signal output circuit for implementing a diagnostic process that satisfies “f_{CLK}=f_{HIGH}”, the control signal output circuit for implementing a diagnostic process that satisfies “f_{CLK}=f_{LOW}”, and the control signal output circuit for implementing a diagnostic process that satisfies “f_{CLK}=f_{REF}”, any of the frequencies f_{HIGH}, f_{LOW}, and f_{REF} can be selectively set with respect to the clock frequency f_{CLK} in the diagnostic sequence operation.

### Ninth Example

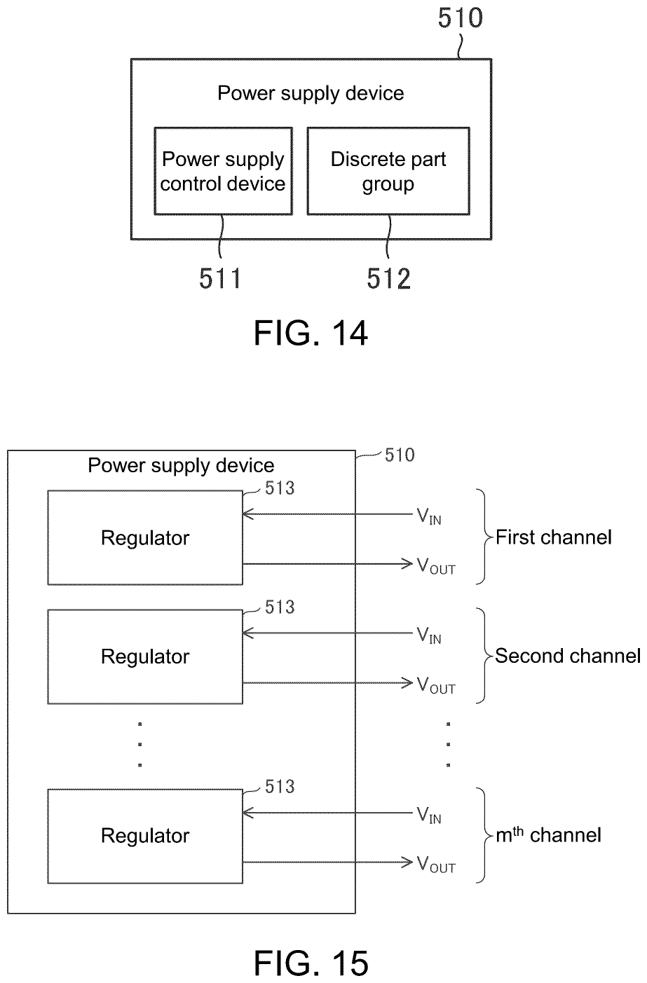

The ninth example will be described. An example of the configuration of a power supply device using the semiconductor device 1 will be presented. FIG. 14 is a schematic configuration block diagram of a power supply device 510 according to the ninth example. The power supply device 510 includes a power supply control device 511, and a discrete part group 512 formed by multiple discrete parts that are externally connected to the power supply control device 511. In the ninth example, the semiconductor device 1 is the power supply control device 511. The power supply control device 511 may be an electronic component classified as a power management IC (PMIC).

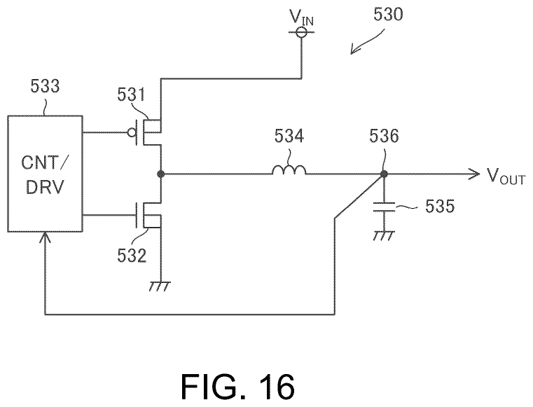

As shown in FIG. 15, the power supply device 510 is provided with m channels of regulators 513, that is, m regulators 513 are provided in the power supply device 510. m represents an arbitrary integer of 2 or more. The m channels of regulators 513 can also be expressed as m channels of power supply devices. In such case, the power supply device 510 can also be referred to as a composite power supply device having m channels of power supply devices (513).

The m channels are formed by the first to the m^{th} channels. Each regulator 513 receives the input voltage V_{IN}, and generates an output voltage V_{OUT} by performing power conversion of the input voltage V_{IN}. In each channel, the input voltage V_{IN} and an output voltage V_{OUT} are DC voltages different from each other. The total m output voltages V_{OUT} in the first to m^{th} channels are different DC voltages from each other. However, among the m output voltages V_{OUT}, it is possible that the values of two or more output voltages V_{OUT} may match. The total m input voltages V_{IN} in the first to m^{th} channels may be different DC voltages from each other, or among the m input voltages V_{IN}, two or more input voltages V^{IN} may be common DC voltages. The input voltage V_{IN} of any of the first to m^{th} channels may be the power supply voltage of the power supply control device 511 (corresponding to the power supply voltage V_{PW} in FIG. 1).

One or more channels of the regulators 513 in the first to m^{th} channels may be switching regulators. The regulator 513 as a switching regulator may be a step-down switching regulator that generates an output voltage V_{OUT} lower than the input voltage V_{IN} by stepping down the input voltage V_{IN}, or a step-up switching regulator that generates an output voltage V_{OUT} higher than the input voltage V_{IN} by stepping up the input voltage V_{IN}. One or more channels of the regulators 513 in the first to m^{th} channels may be linear regulators. All of the total m regulators 513 in the first to m^{th} channels may be switching regulators, or all of the total m regulators 513 in the first to m^{th} channels may be linear regulators. Among the total m regulators 513 in the first to m^{th} channels, one or more switching regulators and one or more linear regulators may be mixed.

FIG. 16 shows the configuration of a regulator 530 that can be used as the regulator 513 for one or more channels. The regulator 530 is a step-down switching regulator and includes transistors 531 and 532, a control drive circuit 533, a coil 534, and a capacitor 535. The transistors 531 and 532 and the control drive circuit 533 are provided in the power supply control device 511. The control drive circuit 533 is portion of the functional circuit. The transistors 531 and 532 are included in the components of the analog block 20. The coil 534 and the capacitor 535 are included in the components of the discrete part group 512. The transistor 531 is a P-channel MOSFET, and the transistor 532 is an N-channel MOSFET. The input voltage V_{IN} is supplied to the source of the transistor 531. The respective drains of the transistors 531 and 532 are connected to the first end of the coil 534. The source of the transistor 532 is connected to the ground. The second end of the coil 534 is connected to an output node 536. The first end of the capacitor 535 is connected to the output node 536, and the second end of the capacitor 535 is connected to the ground. During the period in which power conversion is performed in the regulator 530, the control drive circuit 533 performs switching control to alternately turn on and off the transistors 531 and 532 based on feedback information of the output voltage V_{OUT}, thereby generating the output voltage V_{OUT} at the output node 536. The output voltage V_{OUT} itself or a voltage division of the output voltage V_{OUT} is input to the control drive circuit 533 as feedback information of the output voltage V_{OUT}.

The power supply device 510 performs an operation (power conversion) to generate the output voltage V_{OUT} from the input voltage V_{IN} for each channel. In the power supply control device 511 as the semiconductor device 1, the functional circuit configured with the logic circuit 110 and the analog block 20 controls the power conversion of the regulator 513 for each channel. That is, in the functional operation according to the ninth example (see Step S6 in FIG. 3), the power conversion of the regulator 513 is controlled for each channel.

The control of power conversion also includes the control of whether to execute power conversion. Prior to reaching Step S6, the regulators 513 of all the channels are stopped. When the flow transitions from Step S5 to Step S6, the functional circuit configured with the logic circuit 110 and the analog block 20 sequentially starts the power conversion of the regulators 513 for the 1^{st} to m^{th} channels in a predetermined order. For example, in the case of “m=3”, in response to proceeding from Step S5 to Step S6, the functional circuit starts the power conversion of the regulator 513 for the i_{A}^{th} channel to raise the output voltage V_{OUT} of the i_{A}^{th} channel to a target voltage, then starts the power conversion of the regulator 513 for the i_{B}^{th} channel to raise the output voltage V_{OUT} of the i_{B}^{th} channel to a target voltage, and furthermore after that, starts the power conversion of the regulator 513 for the i_{C}^{th} channel to raise the output voltage V_{OUT} of the i_{C}^{th} channel to a target voltage (where i_{A}^{th}, i_{B}^{th}, and i_{C}^{th} are different natural numbers not exceeding 3). However, in Step S6, the functional circuit may simultaneously start the power conversion of the regulators 513 for two or more channels. In the normal operating state, the power conversion of the regulators 513 for the 1^{st} to m^{th} channels is all continuously executed.

In the case of proceeding from Step S5 to Step S10, the functional circuit does not start the functional operation. That is, in the case of proceeding from Step S5 to Step S10, the functional circuit stops the power conversion of the regulators 513 for the 1^{st} to m^{th} channels (in other words, sets the power conversion of the regulators 513 in the 1^{st} to m^{th} channels to non-execution). In the regulator 530 of FIG. 16, the power conversion of the regulator 530 is stopped by the control drive circuit 533 maintaining both transistors 531 and 532 in the OFF state.

### Tenth Example

The tenth example will be described.

In the ninth example, a configuration in which the semiconductor device 1 is the power supply control device 511 is shown, but the type of the semiconductor device 1 can be arbitrary as long as it is a semiconductor device having a logic circuit to which the diagnostic process according to BIST should be applied. For example, the semiconductor device 1 may be a motor driver that performs drive control of a three-phase motor, and in such case, the functional operation is an operation that performs drive control on the three-phase motor by supplying a three-phase AC voltage to the three-phase motor. Alternatively, for example, the semiconductor device 1 may be a light emitting diode (LED) driver that performs drive control on an LED, and in such case, the functional operation is an operation that performs light emission control on the LED by supplying a current to the LED. Besides, the functional operation can be arbitrary.

The types of channels of the field effect transistors (FETs) shown in the above examples are illustrative. Without affecting the above principles, the channel type of any FET may be changed between P-channel type and N-channel type.

As long as no inconvenience occurs, any transistor mentioned above may be of any type. For example, any transistor described above as a MOSFET may be replaced with a junction FET, an insulated gate bipolar transistor (IGBT), or a bipolar transistor as long as no inconvenience occurs. Any transistor has a first electrode, a second electrode, and a control electrode. In an FET, one of the first and second electrodes is a drain and the other is a source, and the control electrode is a gate. In an IGBT, one of the first and second electrodes is a collector and the other is an emitter, and the control electrode is a gate. In a bipolar transistor that does not belong to an IGBT, one of the first and second electrodes is a collector and the other is an emitter, and the control electrode is a base.

The examples of the disclosure may be appropriately modified in various ways within the scope of the technical concept shown in the claims. The above examples are merely examples of the disclosure, and the meanings of the terms of the disclosure of the respective components are not limited to those described in the above examples. The specific numerical values shown in the above description are merely illustrative and can, of course, be changed to various numerical values.

### APPENDIX

An appendix is provided for the disclosure for which specific configuration examples have been shown in the above examples.

A semiconductor device (1) according to an aspect of the disclosure has a configuration (first configuration) of including: a logic circuit (110); a diagnostic circuit (120), configured so as to perform a diagnostic process of diagnosing whether the logic circuit is in a state capable of normal operation based on output data of the logic circuit when a test pattern is supplied to the logic circuit. The diagnostic circuit executes multiple diagnostic processes with operating conditions of the logic circuit that differ from each other.

Accordingly, it is possible to perform diagnosis of whether the logic circuit is in a state capable of normal operation by also considering cases where operating conditions fluctuate. Therefore, a semiconductor device with high reliability can be provided.

In the semiconductor device according to the first configuration, it may also be configured (second configuration) that: the logic circuit has a sequential circuit (SQC) configured to operate in synchronization with a clock signal, and the diagnostic processes comprise a first diagnostic process, a second diagnostic process, and a third diagnostic process, and the diagnostic circuit causes drive voltages (VDD) of the logic circuit to be different from one another and frequencies (f_{CLK}) of the clock signal to be different from one another among a first diagnostic process to a third diagnostic process.

In the semiconductor device according to the second configuration, it may also be configured (third configuration) that: in the first diagnostic process, the drive voltage of the logic circuit is a reference voltage (VDD_{REF}) and the frequency of the clock signal is a reference frequency (f_{REF}), in the second diagnostic process, the drive voltage of the logic circuit is lower than the reference voltage and the frequency of the clock signal is lower than the reference frequency, and in the third diagnostic process, the drive voltage of the logic circuit is higher than the reference voltage and the frequency of the clock signal is higher than the reference frequency.

In the semiconductor device according to the third configuration, it may also be configured (fourth configuration) that: the diagnostic processes further comprise a fourth diagnostic process and a fifth diagnostic process, in the fourth diagnostic process, the drive voltage of the logic circuit is lower than the reference voltage and the frequency of the clock signal is higher than the reference frequency, and in the fifth diagnostic process, the drive voltage of the logic circuit is higher than the reference voltage and the frequency of the clock signal is lower than the reference frequency.

In the semiconductor device according to the first configuration, it may also be configured (fifth configuration) that: the logic circuit has a sequential circuit (SQC) configured to operate in synchronization with a clock signal, the diagnostic processes comprise a first diagnostic process and a second diagnostic process, and the diagnostic circuit causes drive voltages (VDD) of the logic circuit to be different from one another and frequencies (f_{CLK}) of a clock signal to be different from one another between a first diagnostic process and a second diagnostic process.

In the semiconductor device according to the first configuration, it may also be configured (sixth configuration) that: the drive voltage of the logic circuit in the second diagnostic process is higher than the drive voltage of the logic circuit in the first diagnostic process, and the frequency of the clock signal in the second diagnostic process is higher than the frequency of the clock signal in the first diagnostic process.

In the semiconductor device according to the first configuration, it may also be configured (seventh configuration) that: the diagnostic circuit causes drive voltages (VDD) of the logic circuit to be different from one another among the diagnostic processes.

In the semiconductor device according to the first configuration, it may also be configured (eighth configuration) that: the logic circuit has a sequential circuit (SQC) configured to operate in synchronization with a clock signal, and the diagnostic circuit causes frequencies (f_{CLK}) of the clock signal to be different from one another among the diagnostic processes.

In the semiconductor device according to the first to eighth configurations, it may also be configured (ninth configuration) that: the semiconductor device is a power supply control device (511) configured to control an operation of a power supply device (510) by using the logic circuit, the power supply device has a regulator (513) of multiple channels, and is configured to be able to execute power conversion that generates an output voltage (V_{OUT}) from an input voltage (V_{IN}) for each channel, the diagnostic circuit derives first result data (“0” of FLG) or second result data (“1” of FLG) through the diagnostic processes, and the semiconductor device starts the power conversion in each of the channels after the first result data is derived by the diagnostic circuit, and stops the power conversion in each of the channels in a case where the second result data is derived by the diagnostic circuit.

What is claimed is:

1. A semiconductor device, comprising:
a logic circuit;
a diagnostic circuit, configured so as to perform a diagnostic process of diagnosing whether the logic circuit is in a state capable of normal operation based on output data of the logic circuit when a test pattern is supplied to the logic circuit, and
wherein the diagnostic circuit executes a plurality of diagnostic processes with operating conditions of the logic circuit that differ from each other.

2. The semiconductor device as claimed in claim 1, wherein the logic circuit has a sequential circuit configured to operate in synchronization with a clock signal,
the diagnostic processes comprise a first diagnostic process, a second diagnostic process, and a third diagnostic process, and
the diagnostic circuit causes drive voltages of the logic circuit to be different from one another and frequencies of the clock signal to be different from one another among a first diagnostic process to a third diagnostic process.

3. The semiconductor device as claimed in claim 2, wherein, in the first diagnostic process, the drive voltage of the logic circuit is a reference voltage and the frequency of the clock signal is a reference frequency,
in the second diagnostic process, the drive voltage of the logic circuit is lower than the reference voltage and the frequency of the clock signal is lower than the reference frequency, and
in the third diagnostic process, the drive voltage of the logic circuit is higher than the reference voltage and the frequency of the clock signal is higher than the reference frequency.

4. The semiconductor device as claimed in claim 3, wherein the diagnostic processes further comprise a fourth diagnostic process and a fifth diagnostic process,
in the fourth diagnostic process, the drive voltage of the logic circuit is lower than the reference voltage and the frequency of the clock signal is higher than the reference frequency, and
in the fifth diagnostic process, the drive voltage of the logic circuit is higher than the reference voltage and the frequency of the clock signal is lower than the reference frequency.

5. The semiconductor device as claimed in claim 1, wherein the logic circuit has a sequential circuit configured to operate in synchronization with a clock signal,
the diagnostic processes comprise a first diagnostic process and a second diagnostic process, and
the diagnostic circuit causes drive voltages of the logic circuit to be different from one another and frequencies of a clock signal to be different from one another between a first diagnostic process and a second diagnostic process.

6. The semiconductor device as claimed in claim 5, wherein the drive voltage of the logic circuit in the second diagnostic process is higher than the drive voltage of the logic circuit in the first diagnostic process, and
the frequency of the clock signal in the second diagnostic process is higher than the frequency of the clock signal in the first diagnostic process.

7. The semiconductor device as claimed in claim 1, wherein the diagnostic circuit causes drive voltages of the logic circuit to be different from one another among the diagnostic processes.

8. The semiconductor device as claimed in claim 1, wherein the logic circuit has a sequential circuit configured to operate in synchronization with a clock signal, and
the diagnostic circuit causes frequencies of the clock signal to be different from one another among the diagnostic processes.

9. The semiconductor device as claimed in claim 1, wherein the semiconductor device is a power supply control device configured to control an operation of a power supply device by using the logic circuit,
the power supply device has a regulator of a plurality of channels, and is configured to be able to execute power conversion that generates an output voltage from an input voltage for each channel,
the diagnostic circuit derives first result data or second result data through the diagnostic processes, and
the semiconductor device starts the power conversion in each of the channels after the first result data is derived by the diagnostic circuit, and stops the power conversion in each of the channels in a case where the second result data is derived by the diagnostic circuit.
